(19) United States
(12) Patent Application Publication
(10) Pub. No.: US 2001/0020749 A1
(43) Pub. Date: Sep. 13, 2001

(54) Bond-pad with pad edge strengthening structure

(76) Inventors: Shi-Tron Lin, Hsinchu (TW); Chin-Jong Chan, Hsinchu (TW)

Correspondence Address: LAW OFFICE OF LIAUH & ASSOC., 4224 WAIALAE AVE, STE 5-388, HONOLULU, HI, 96816

(21) Appl. No.: 09/832,226

(22) Filed: Apr. 9, 2001

Related U.S. Application Data
(63) Continuation-in-part of application No. 09/327,876, filed on Jun. 8, 1999.

(51) Int. Cl. H01L 23/48; H01L 23/52; H01L 29/40

(52) U.S. Cl. 257/782

(57) ABSTRACT

A bond pad structure for use in wire bonding applications during the packaging of semiconductor devices which minimizes the bond pad lift-off problem to provide improved stability. The bond pad structure contains: (1) a dielectric layer 4 formed on a first conductive layer 5; (2) a base conductive layer (whose outer boundary as viewed from the top is indicated as line 11) formed in the dielectric layer on top of the first conductive layer, the base conductive being extended to form an overhang layer (whose outer boundary is shown as line 13) which is disposed above the dielectric layer; and (3) at least one recessed portion 20 formed in the overhang layer. In a preferred embodiment, the bond pad is rectangular in shape and the recessed portion has the shape of an elongated rim that covers two corners of the base conductive layer.

This is a continuation-in-part application ofU.S. application Ser. No. 09/327,876, filed, Jun. 8, 1999.

### FIELD OF THE INVENTION

The present invention relates to a novel bond-pad structure for use in semiconductor packaging applications with improved stability. More specifically, the present invention relates to an improved bond-pad structure which eliminates or at least minimizes the bond-pad lift-off (or peeling-off) problems often encountered during the wire bonding step in the packaging of integrated circuits (ICs). With the improved bond-pad structure of the present invention, the failure rate in production yield due to bond-pad lift-off can be substantially reduced without requiring major modifications in the fabrication process or facility. The present invention also relates to a novel process which implements the improved bond-pad design to increase the production yield so as to reduce the overall production costs for the manufacturing of integrated circuit packages, as well as to the printed circuit boards (PCBs) or other integrated circuit packages that incorporate the improved bond-pad structure disclosed herein.

### BACKGROUND OF THE INVENTION

During the formation of printed circuit boards (PCBs) or other integrated circuit (IC) packaging processes, the semiconductor devices provided in the printed circuit board can be respectively connected to the outside sources or sinks via a wire-bonding process. In such a process, one or more bonding pads are provided which are in contact with respective parts of the semiconductive device at the outer-most conductive layer thereof. Then, a bonding wire is bonded onto the bond pad so as to allow the semiconductor device to make electric contact with the inner lead of the IC package. Typically, the wire bonding process can be approximately categorized into two main types: the gold wire/gold ball bonding process and the aluminum wire wedge bonding process. The aluminum wire wedge bonding process is widely used in chip-on-board (COB) applications in which the aluminum wire is welded to the bond pad via a combination of ultrasonic vibrations and pressure applied to the wedge. The gold wire/gold ball bonding process is typically accomplished by pressing the wire, which is first formed into a ball, against the bond pad at an elevated temperature. The aluminum wire wedge bonding process is generally less accurate in establishing the bonding position and less uniform in the applied bonding pressure, and, hence, it is more prone to the bond peel-off problem relative to the gold wire/ball bonding process, mainly due to the non-uniformity of mechanical and/or thermal stresses.

The bond peel-off problem occurs when the adhesion force between any adjacent layers in the multi-layer structured semiconductor device is not strong enough to resist the thermal and mechanical stress that may be present during the wire bonding process to bond the bonding wire to the bond pad. This can occur, for example, between the metal bond pad and the underlying polysilicon layer, between a metal layer and a dielectric layer, between a dielectric layer and a polysilicon layer, and between a barrier layer and a dielectric layer, etc.

Bond-pad peeling-off or lift-off, in addition to that discussed above, has been a major unsettling problem besetting the integrated circuit packaging industry involving the wire bonding technology. Many possible solutions have been suggested and implemented, as illustrated in the following prior art references.

U.S. Pat. No. 4,060,828 discloses a semiconductor device having a multi-layer wiring structure with an additional through-hole interconnection formed in the insulating layer beneath the bonding pad of the wiring layer. The purpose of the '828 patent is to provide additional, and protected, electrical contact between the bonding pad and another wiring layer therebelow, such that if the exposed portion of the bonding pad is corroded and thus becoming disconnected, the additional electrical contact formed through the insulation layer can still provide the needed connection. While the '828 patent does not directly address the bond pad peel-off problem, the concept of providing a through-hole interconnection structure in the insulation layer immediately underlying the metal layer as disclosed in the '828 patent has been adopted, though mostly in modified form, by essentially all the prior art processes dealing with solving the problem of bond pad peel-off to provide an anchored structure.

U.S. Pat. No. 4,981,061 discloses a semiconductor device which comprises a first insulating layer formed on the major surface of the semiconductor substrate including an active region. A first contact hole is formed at a position in the first insulating layer corresponding to the active region and a first conductive layer is formed in the first contact hole and a portion of the first insulating layer around the contact hole. Then a second insulating layer is formed on the first conductive layer and the first insulating layer, and a second contact hole is formed at a position in the second insulating layer corresponding to the first conductive layer and located above the first contact hole. Subsequently, a second conductive layer is formed on the second insulating layer and fills the second contact hole. Finally a bonding wire is connected to the second conductive layer in regions located above the first and second contact holes. With the structure disclosed in the '061 patent, the pressure applied to the second insulating layer during wire bonding is supported by columnar portions of the first and second conductive layers filled in the first and second contact holes. Thus, the pressure acting on the second insulating layer is reduced to suppress occurrence of cracks.

U.S. Pat. No. 5,309,205 discloses a bond pad structure which is formed by depositing a barrier layer over an underlying region of a semiconductor device, and then depositing a first conductive layer over the barrier layer. The barrier layer and conductive layer are then patterned and etched to define a conductive region. In the '205 patent, the conductive region is formed in the shape of a grid, and a second conductive layer is deposited over the conductive region and a portion of the exposed underlying region. The second conductive layer makes a good adhesive contact with the underlying region, thus preventing bond pad lift off.

U.S. Pat. No. 5,248,903 discloses a bond pad structure which alleviates bond pad lift problems encountered during wire bonding by providing a composite bond pad, which includes an upper bond pad and a lower bond pad, and an insulating component therebetween. At least one opening is provided through the insulating component, extending from the bottom bond pad to the upper bond pad. The at least one opening is aligned with a peripheral region of the bottom bond pad. A conductive material is then provided which fills the plurality of openings, and electrically connects the top and bottom bond pads. The at least one opening can be a plurality of conductive vias, a ring-like opening extending around the peripheral region, or one or more elongated slit-like openings.

U.S. Pat. No. 5,309,025 discloses an improved bond pad structure which reduces bond pad lift off problems. The bond pad disclosed in the '025 patent includes a barrier layer, and is formed by first depositing a barrier layer over an underlying region of a semiconductor device, and then depositing a first conductive layer over the barrier layer. The barrier layer and the conductive layer are then patterned and etched to define a conductive region. A plurality of the conductive regions are formed each of which is isolated from the ourside by the formation of an insulative sidewall. A second conductive layer is deposited over the conductive region and a portion of the exposed underlying region. The second conductive layer makes a good adhesive contact with the underlying region, thus preventing bond pad lift off.

U.S. Pat. No. 5,707,894 discloses an improved bonding pad structure and the process for forming the same which reduces the bond pad peeling problem between the bonding pad layer and an underlying layer. The method disclosed in the '894 patent comprises the steps of first forming a plurality of anchor pads on the substrate surface in the bonding pad area. Next, a first insulating layer is formed over the substrate surface and the anchor pads. A plurality of via holes are formed through the first insulating layer which are filled with the same material as a second metal layer, which covers the first insulation layer, so as to form a conductive connection anchor pads and the second metal layer. The via holes have a smaller cross-sectional area than the anchor pads so that the combination of the anchor pads and the second metal form small “hooks” into the first insulating layer that hold the second metal layer (i.e., the bonding pad layer) to the underlying layer.

All of the prior art inventions discussed above failed to notice another important cause for the bond pad peel-off problems. It was observed by the co-inventors of the present invention that, very often, the bond pad peeling problem was found to be caused by cracks formed in or around one or more of the edge portions of the dielectric layer underlying corresponding portions of the metal bonding pad. Once a crack in the edge portion of the dielectric layer is formed due to the thermal and/or mechanical stress during the wire bonding process, it will propagate along the interface between the metal bonding pad and the dielectric layer, and eventually leading to the bond pad to be peeled off from the semiconductor device. Such a bond pad peel-off problem due to crack propagation becomes more profound as the bond pad size becomes smaller.

Furthermore, most of the inventions discussed above involve forming multiple metal-filled holes or vias through the insulation layer underneath the portion of the bond pad where bonding wire is to be attached wherein the heat rise is expected to be high. The multiple metal-filled vias are not interconnected to each other except indirectly at the top through their respective connections to the metal layer. If the multiple metal-filled vias are not laid out properly, or if the wire bonding is not applied on the location as designed, unequal heat transfers from the metal bond pad layer in the different metal-filled vias can cause undesirable thermal stress problems.

U.S. pat. app. Ser. No. 09/327,876, the content thereof is incorporated herein by reference, taught a new bond pad structure in which at least one dendritic sub-structure is formed extending from the edge portion of the metal bond pad into the adjacent dielectric layer. The dendritic substructure is substantially smaller in dimension than the bond pad itself. This bond pad structure is prepared by forming one or more dendritically-shaped through holes along the edge of the dielectric layer. The dendritically shaped through holes are then filled with a metal material which are interconnected to the edge of the metal bond pad to form one or more corresponding dendritic sub-structures. The dendritic sub-structure of the '876 invention serves two main purposes. First, it creates an augmented contact area, and thus an enhanced adhesive force, for the metal bond pad, due to the newly created vertically extending contact surfaces between the metal bond pad layer and the dielectric layer in the dendritic sub-structure. Second, the dendritic sub-structure creates a discontinuity in the edge portion of the dielectric layer which, when designed properly, can effectively intercept and thus stop the growth of cracks after they are formed. As discussed in the '876 invention, crack growth is one of the main reasons contributing to the bond pad peel-off. By stopping the crack growth and providing and enhanced adhesion, the dendritically-structured bond pad design has proven to be more effective than any of the prior art structures in preventing the bond pad lift-off problem. Also, since the bond pad of the '876 invention does not involve forming any vias or anchoring structures in the insulation layer in the area beneath the bond pad, it can be much more easily implemented. This procedural advantage translates into substantial cost savings.

### SUMMARY OF THE INVENTION

The primary object of the present invention is to develop an improved bond pad structure for use in wire bonding applications during the packaging operation of manufacturing integrated circuit devices. More specifically, the primary object of the present invention is to develop an improved bond pad structure which minimizes the lift-off problem and which is relatively easy and inexpensive to implement.

The inventors of the present invention unexpectedly discovered that by forming a rim portion from the base portion of the bond pad that covers at least two corners of the base portion of the bond pad, the resultant bond pad structure is at least as stable as that disclosed in the '876 invention which contains a dendritic sub-structure. However, the bond pad structure is advantageous than that in the '876 invention in that, since the dendritic sub-structure must be substantially smaller than the bond pad itself, as the semiconductor devices become smaller, the bond pond structure becomes easier to manufacture than that of the '876 invention.

The present invention can be advantageously implemented in a wide variety of bond pad configurations. To illustrate how the present invention works, one must look at a typical bond pad structure as shown in FIG. 1, wherein the bond pad structure 10 is formed directly on a polysilicon layer 5. FIG. 1 shows that the bond pad structure 10, which is rectangular in shape, contains a base portion 1, a sidewall portion 2, which is extended to form an overhang portion 3 on top of the dielectric layer 4. The base portion 1 is typically called a bond pad metal layer. Because the extent of the contacting surface, and thus the adhesive force so provided, is only very limited, the bond pad base portion 1 can be peeled off from the polysilicon layer when the vibrational or thermal stress exceeds a certain level. Most of the prior art methods, such as those discussed above, involve the concept of “elevating” the metal bond pad layer and extending the dielectric layer into the region directly underneath the bond pad so as to allow the formation of a multiplicity of vias or anchoring structures to provide the desired adhesion and thus stability.

In the present invention, at least one recess is formed in the overhanging portion 3 of the bond pad structure. Because the recess and the bottom portion are typically formed from the same step as the base portion, it is typically positioned at the same level with the base portion. Indeed, the recessed portion can be envisioned as if the overhanging portion and its adjacent sidewall were pushed downward, so as to create such a recess, which lays flat relative to the base portion as if it were an extension of the base portion. Such a discontinuity in the overhang portion creates an anchoring structure.

The inventors of the present invention have discovered that, if the recess is made as a rim that covering at least two corners of the base portion, the bond pad structure provides the desired stability and is also very easy to fabricate. In this configuration, the base portion becomes two rectangles of different dimensions connected, top-to-bottom, adjacent to each other. The presence of the recess creates a drop-off in the overhang portion, it also increases the contact area between the base portion and the underlying polysilicon layer.

In another embodiment of the present invention, the recessed portion is expanded to cover three corners of the base portion. In all the embodiments, the recessed portion in the overhang portion can be extended such that its edge is within 3 μm from the edge of the overhang portion (in other words, the remaining overhang portion adjacent to the recessed portion has a thickness of no greater than 3 μm).

In summary, the improved bond pad structure of the present invention contains the following key elements:

(1) a dielectric layer formed on a first conductive layer;

(2) a base conductive layer formed in the dielectric layer on top of the first conductive layer, the base conductive being extended to form an overhang layer which is disposed above the dielectric layer; and

(3) at least one recessed portion (or depression) formed in the overhang layer.

The depression is typically formed as a rim (i.e., an extension) from the base layer, but is formed in a projected horizontal location that was occupied by the overhang portion (when viewed from the top view diagram). The depression can be relatively extensive such that it becomes a continuous rim that encompasses two or even three corners of the base portion.

### BRIEF DESCRIPTION OF THE DRAWING

The present invention will be described in detail with reference to the drawing showing the preferred embodiment of the present invention, wherein:

FIG. 1 is an illustrative schematic diagram showing a side view of a conventional bond pad structure without any anchoring structure.

FIG. 2 is an illustrative schematic diagram showing the top view of the bond pad structure disclosed in the '876 invention, which contains an array of dendritically shaped sub-structures outside of and along each of the four sides of the bond pad open area.

FIG. 3 is an illustrative schematic diagram showing the top view of the conventional bond pad structure shown in FIG. 1.

FIG. 4 is an illustrative schematic diagram showing the top view of the improved bond pad structure of the present invention showing a recessed portion is formed in the overhang layer of the bond pad.

FIG. 5 is an illustrative schematic diagram showing the top view of the improved bond pad structure according to a preferred embodiment of the present invention in which the rim portion of the base layer (which can also be considered as the recessed portion of the overhang layer) covers two corners of the base layer.

FIG. 6 is an illustrative schematic diagram showing a cross-sectional view along line 6-6′ of the improved bond pad as shown in FIG. 5.

FIG. 7 is an illustrative schematic diagram showing a cross-sectional view along line 7-7′ of the improved bond pad as shown in FIG. 5.

FIG. 8 is an illustrative schematic diagram showing the top view of the improved bond pad structure according to a preferred embodiment of the present invention in which the rim portion of the base layer covers three corners of the base layer.

FIG. 9 is an illustrative schematic diagram showing a cross-sectional view along line 9-9′ of the improved bond pad as shown in FIG. 8.

FIG. 10 is an illustrative schematic diagram showing a cross-sectional view along line 10-10′ of the improved bond pad as shown in FIG. 8.

### DETAILED DESCRIPTION OF THE PREFERRED EMBODIMENT

The present invention discloses an improved bond pad structure for use in wire bonding applications during the packaging operation of manufacturing integrated circuit devices by minimizing or eliminating the lift-off problems. The improved bond pad structure of the present invention is also easy and inexpensive to fabricate.

As discussed above, the inventors of the present invention unexpectedly discovered that by forming a rim portion extending from the base layer of the bond pad structure that covers at least two corners of the base layer, the resultant bond pad structure provides at least as much stability improvement as that disclosed in the '876 invention which contains a dendritic sub-structure. However, the bond pad structure of the present invention is advantageous than that in the '876 invention in that is can be easier to fabricate especially with increasingly reduced dimensions of semiconductor devices.

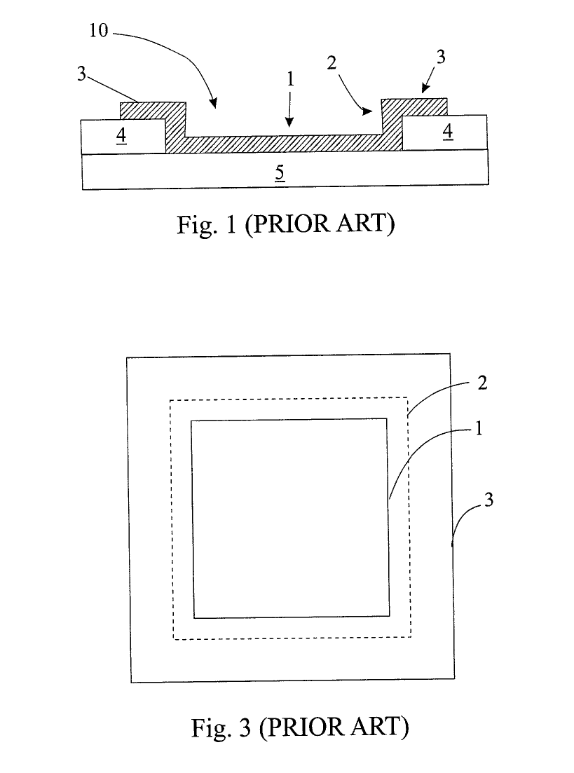

FIG. 1 is an illustrative schematic diagram showing a side view of a conventional bond pad structure without any anchoring structure, wherein the bond pad structure 10 is formed directly on a polysilicon layer 5. In FIG. 1, it is also shown that the bond pad structure 10, which is rectangular in shape, contains a horizonally extending base layer 1, a vertically extending sidewall layer 2, which is bent and then further extended to form an overhang layer 3 on top of the dielectric layer 4. The base layer 1 is typically called a bond pad metal layer. If the base layer 1 is formed to have the same thickness as that of the dielectric layer 4, then, obviously, the sidewall layer 2 will merge with the overhang layer 3.

FIG. 3 is an illustrative schematic diagram showing the top view of the conventional bond pad structure shown in FIG. 1. The base layer 1 and the overhang layer 3 are on different elevations, and they are connected by a vertically extending sidewall layer 2.

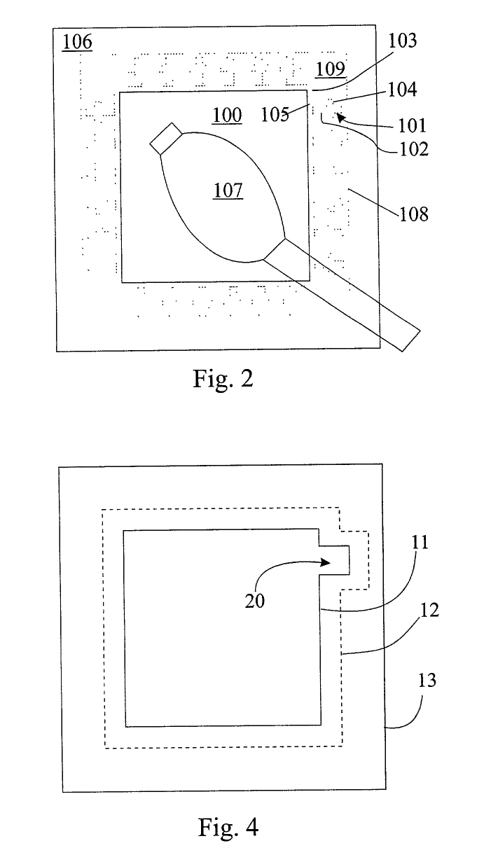

FIG. 2 is an illustrative schematic diagram showing the top view of the bond pad structure disclosed in the '876 invention, which contains an array of dendritically shaped sub-structures outside of and along each of the four sides of the bond pad open area. In FIG. 2, it is shown a bond pad structure which contains an array of cross-shaped dendritic sub-structures 101 outside of and along each of the four sides of the bond pad 100. Each of the dendritic sub-structures has a long segment 102 which is perpendicular to the edge 103 of the bond pad 100, and a short segment 111 which is parallel to the edge 103 of the bond pad 100. The dendritic sub-structures 101 are formed into the dielectric layer 104. The dendritic sub-structures 101, the dielectric layer 104, and, optionally, a small edge portion 105 of the bond pad are covered by a passivation layer 106. A gold wire/ball 107 is bonded onto the bond pad 100. Dotted line 108 indicates the edge of the overhang portion 109 of the bond pad 100. The gold wire/ball can be replaced with an aluminum material.

In the present invention, at least one recess is formed in the overhanging portion 3 of the bond pad structure. Because the recess and the bottom portion are typically formed from the same step, it is typically positioned at the same level with the base portion. Indeed, the recessed portion can be envisioned as pushing downward a portion of the overhanging portion and its adjacent sidewall, so as to create such a recess, which lays flat relative to the base portion as if it were an extension of the base portion.

In summary, as shown in FIG. 4, which is an illustrative schematic diagram showing the top view of the improved bond pad structure of the present invention having a recessed portion is formed in the overhang layer of the bond pad, in conjunction with FIG. 1, the present invention discloses an improved bond pad structure which contains the following main elements:

(1) a dielectric layer 4 formed on a first conductive layer 5;

(2) a base conductive layer (whose outer boundary as viewed from the top is shown as line 11) formed in the dielectric layer on top of the first conductive layer, the base conductive being extended to form an overhang layer (whose outer boundary is shown as line 13) which is disposed above the dielectric layer; and

(3) at least one recessed portion 20 formed in the overhang layer.

The outer boundary of the entire base layer, which is hidden behind the overhang, is shown as the dashed line 12. The recessed portion is typically formed as a rim (i.e., an extension) from the base layer, but is formed in a horizontal location that was occupied by the overhang portion (when viewed from the top view diagram). The depression can be relatively extensive such that it covers two or even three corners of the base portion. As discussed the inventors of the present invention have discovered that, if the recess is made as a rim that covers at least two corners of the base portion, the bond pad structure provides excellent stability while being very easy to fabricate. In another embodiment of the present invention, the recessed portion is expanded to cover three corners of the base portion. In all the embodiments, the recessed portion in the overhang portion can be extended such that it edge is within 3 μm from the edge of the overhang portion (in other words, the remaining overhang portion adjacent to the recessed portion has a thickness of no greater than 3 μm).

The present invention will now be described more specifically with reference to the following examples. It is to be noted that the following descriptions of examples, including the preferred embodiment of this invention, are presented herein for purposes of illustration and description, and are not intended to be exhaustive or to limit the invention to the precise form disclosed.

### Example 1

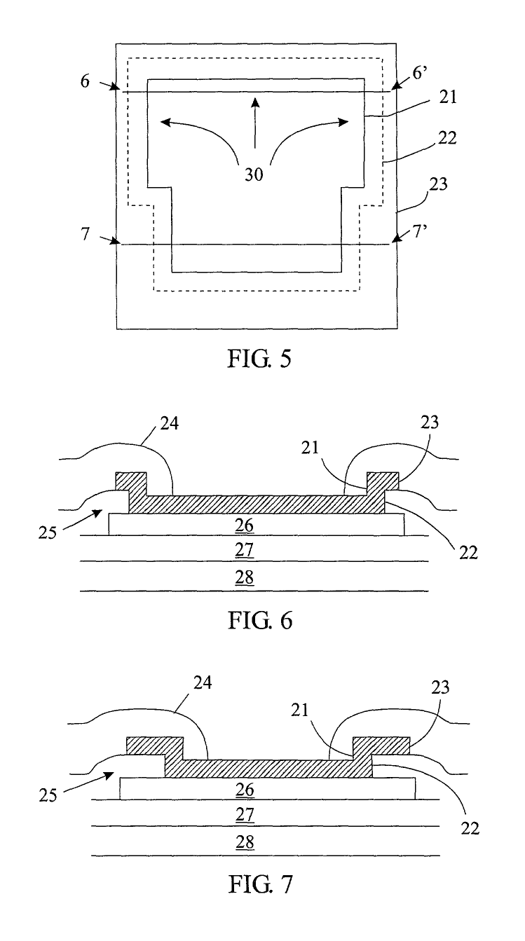

FIG. 5 is an illustrative schematic diagram showing the top view of the improved bond pad structure according to a preferred embodiment of the present invention in which the rim portion of the base layer (which can also be considered as the recessed portion of the overhang layer) covers two corners of the base layer. FIG. 6 is an illustrative schematic diagram showing a cross-sectional view along line 6-6′ of the improved bond pad as shown in FIG. 5. And FIG. 7 is an illustrative schematic diagram showing a cross-sectional view along line 7-7′ of the improved bond pad as shown in FIG. 5.

In FIGS. 5-7, it is shows that the base layer (whose outer boundary is indicated by dashed line 22) of the bond pad structure of the present invention is formed on a polysilicon layer 26, which, in turn, is formed on a field oxide 27 and a silicon substrate 28. Line 23 indicates the outer boundary of the overhang portion of the bond pad. When viewed from the top, the base layer is shown to have an outer boundary as indicated by line 21. The space between line 21 and 22 can be considered as the vertically extending sidewall layer.

One of the main advantages of the improved bond pad structure of the present invention is that it only involves minor modifications from the conventional bond pad structure. In the first preferred embodiment as shown in FIG. 5, a rim 30 is formed around the top edge and top portions of the two adjacent side edges of the base layer 21 such that it covers two corners of the base portion. The base layer is then stepped up to form the sidewall layer and the overhang layer. Because the final bond pad structure has a rectangular shape (i.e., each edge of the overhang layer is a straight line), the portion of the overhang layer where the rim portion of the base layer exists (i.e., FIG. 6) has a narrower thickness than the portion where there is no rim portion (i.e., FIG. 7). The rim portion 30 extending from the base layer 21 can be considered as a recessed portion in the overhang layer 23, as shown in FIG. 5. The recessed portion 30 in the overhang portion can be extended horizontally such that its edge is within 3 μm from the edge of the overhang portion 23 (i.e., the distance between dashed line 21 and solid line 23 is no greater than 3 μm).

### Example 2

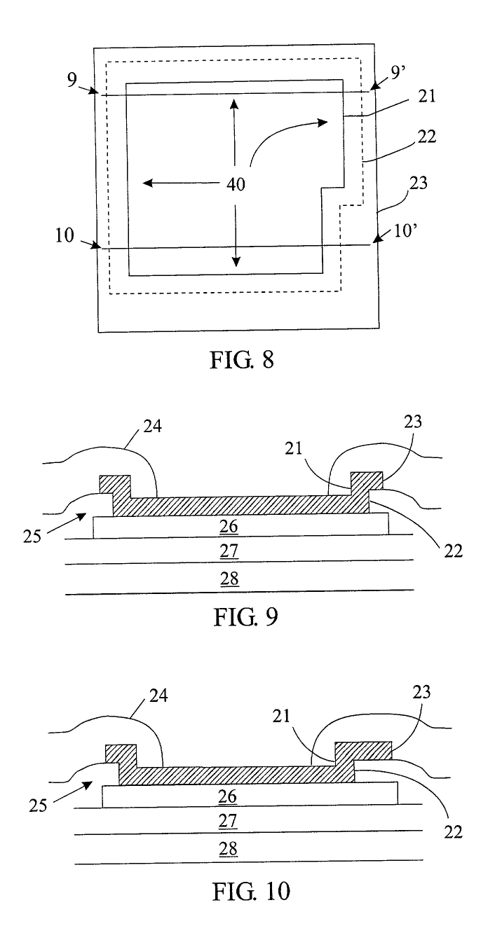

FIG. 8 is an illustrative schematic diagram showing the top view of the improved bond pad structure according to a preferred embodiment of the present invention in which the rim portion 40 of the base layer covers three corners of the base layer. FIG. 9 is an illustrative schematic diagram showing a cross-sectional view along line 9-9′ of the improved bond pad as shown in FIG. 8. FIG. 10 is an illustrative schematic diagram showing a cross-sectional view along line 10-10′ of the improved bond pad as shown in FIG. 8.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A bond pad structure for use in wire bonding application during the packaging operation of semiconductor devices, comprising:
(a) a dielectric layer formed on a first conductive layer;
(b) a base conductive layer formed in said dielectric layer on top of said first conductive layer, said base conductive layer being extended to form an overhang layer which is disposed above said dielectric layer; and
(c) at least one recessed portion formed in said overhang layer.

2. The bond pad structure according to claim 1, wherein said bond pad is rectangular in shape and said recessed portion has the shape of an elongated rim that covers two corners of said base conductive layer.

3. The bond pad structure according to claim 1, wherein said bond pad is rectangular in shape and said recessed portion has the shape of an elongated rim that covers three corners of said base conductive layer.

4. The bond pad structure according to claim 1, wherein said first conductive layer is a polysilicon layer.

5. The bond pad structure according to claim 1, wherein said recessed portion is directly extending from said base layer.

6. The bond pad structure according to claim 1, wherein said base conductive layer and said overhang layer are both metal layers.

7. The bond pad structure according to claim 1, wherein the portion of said overhang layer extending from said recessed portion has a length no greater than 3 μm.

8. An integrated circuit containing a bond pad structure for connecting electricity to semiconductor devices contained in the integrated circuit, said bond pad structure comprising:
(a) a dielectric layer formed on a first conductive layer;
(b) a base conductive layer formed in said dielectric layer on top of said first conductive layer, said base conductive layer being extended to form an overhang layer which is disposed above said dielectric layer; and
(c) at least one recessed portion formed in said overhang layer.

9. The integrated circuit according to claim 8, wherein said bond pad is rectangular in shape and said recessed portion has the shape of an elongated rim that covers two corners of said base conductive layer.

10. The integrated circuit according to claim 8, wherein said bond pad is rectangular in shape and said recessed portion has the shape of an elongated rim that covers three corners of said base conductive layer.

11. The integrated circuit according to claim 8, wherein said first conductive layer is a polysilicon layer.

12. The integrated circuit according to claim 8, wherein said recessed portion is directly extending from said base layer.

13. The integrated circuit according to claim 8, wherein said base conductive layer and said overhang layer are both metal layers.

14. The integrated circuit according to claim 8, wherein the portion of said overhang layer extending from said recessed portion has a length no greater than 3 μm.

15. The integrated circuit according to claim 8, wherein said bond pad structure is formed on a semiconductor substrate.
